(19) United States
(12) Patent Application Publication
(10) Pub. No.: US 2016/0105194 A1
(43) Pub. Date: Apr. 14, 2016

(54) PASSIVE ANALOG SAMPLE AND HOLD IN ANALOG-TO-DIGITAL CONVERTERS

(71) Applicant: ANALOG DEVICES TECHNOLOGY, Hamilton (BM)

(72) Inventors: MAHESH MADHAVAN KUMBARANTHODIYIL, VELLIPARAMBA CALICUT (IN); Sandeep Monangi, SRIKAKULAM (IN)

(73) Assignee: ANALOG DEVICES TECHNOLOGY, Hamilton (BM)

(21) Appl. No.: 14/511,613

(22) Filed: Oct. 10, 2014

(51) Int. Cl. H03M 1/12

(52) U.S. Cl. CPC H03M 1/1245

(57) ABSTRACT

In an example embodiment, an analog to digital converter (ADC) facilitating passive analog sample and hold is provided and includes a pair of binary weighted conversion capacitor arrays, a pair of sampling capacitors, and a plurality of switches that configure each conversion capacitor array and the sampling capacitors for a sampling phase, a charge transfer phase, and a bit trial phase. During the sampling phase, the sampling capacitors are decoupled from the conversion capacitors and coupled to an analog input voltage. During the charge transfer phase, the sampling capacitors are coupled to the conversion capacitors and decoupled from the analog input voltage. During the bit trial phase, the sampling capacitors are decoupled from the conversion capacitors.

### TECHNICAL FIELD OF THE DISCLOSURE

The present disclosure relates generally to electrical circuits and, more particularly, to a method and apparatus for passive analog sample and hold in analog-to-digital converters.

### BACKGROUND

Analog-to-digital converters (ADCs), such as successive-approximation-register (SAR) ADCs, which represent the majority of the ADC market for medium- to high-resolution ADCs, can provide up to SMsps sampling rates with resolutions from 8 to 18 bits. The SAR architecture allows for high-performance, low-power ADCs to be packaged in small form factors for demanding applications. Some ADCs implements a binary search algorithm; thus, while the internal circuitry may be running at several megahertz (MHz), the ADC sample rate is a fraction of that number due to the successive-approximation algorithm. Note that the ADC converts an analog signal into a stream of digital numbers (called samples), each sample representing the analog signal's amplitude at a particular moment in time. The number of samples per time interval is called the sampling rate, typically measured in samples per second.

Certain ADCs (e.g., SAR ADCs) generate a digital code representing the magnitude of the input analog voltage (V_{IN}). ADCs operate in two phases—a sampling phase and a bit trial phase. During the sampling phase, the input voltage is acquired. During the bit trial phase, the input voltage is compared against test voltages to determine whether the input voltage is greater than or less than the respective test voltages. Although there are many variations for implementing the ADC, the basic architecture includes a sample-and-hold circuitry that holds V_{IN} on a sample-and-hold during the bit trial phase.

A control logic forces the most significant bit (MSB) of an N-bit register (successive approximation register) to high (e.g., 1). The N-bit register is connected to a Digital-to-Analog Converter (DAC) and the high bit value forces the DAC output (V_{DAC}) to be V_{REF}/2, where V_{REF} is the reference voltage provided to the ADC. Typically, the V_{REF} is the highest allowed level of the input voltage. A comparison between V_{IN} and V_{DAC} is performed by a comparator to determine if V_{IN} is less than, or greater than, V_{DAC}. If V_{IN} is greater than V_{DAC}, the comparator output is a logic high, or 1, and the MSB of the N-bit register remains at 1. Conversely, if V_{IN} is less than V_{DAC}, the comparator output is a logic low and the MSB of the register is cleared to logic 0. The control logic then moves to the next bit down, forces that bit high, and does another comparison. The bit trial process operates incrementally across all bit positions from the MSB to the least significant bit (LSB) position until a complete digital code is generated that corresponds to the input voltage.

Many ADCs use a capacitive DAC that employ charge redistribution to generate an analog output voltage. The capacitive DAC typically consists of an array of capacitors with binary weighted values. Typically, the capacitor used for the MSB (MSB capacitor) has the highest capacitance and the capacitor used for the LSB (LSB capacitor) has the least capacitance. During the sampling phase, the array's common terminal (e.g., the terminal at which all the capacitors share a connection) is connected to ground and all free terminals are connected to the input signal (V_{IN}). After sampling, the common terminal is disconnected from ground and the free terminals are disconnected from V_{IN}, thus effectively trapping a charge proportional to the input voltage on the capacitor array. The free terminals of all the capacitors are then connected to ground, driving the common terminal negative to a voltage equal to −V_{IN}.

As the first step in the binary search algorithm of the bit trial phase, the bottom plate of the MSB capacitor is disconnected from ground and connected to V_{REF}, driving the common terminal in the positive direction by an amount equal to V_{REF}/2. Thus, the voltage on the common terminal is V_{COMMON}=−V_{IN}+V_{REF}/2. The comparator output yields a logic 1 if V_{COMMON}<0 (i.e., V_{IN}>V_{REF}). The comparator output yields logic 0 if V_{IN}<V_{REF}/2. The bottom plate of the next smaller capacitor is connected to V_{REF} and the new V_{COMMON} voltage is compared with ground. The process continues until all the bits have been determined.

Note that most devices use a single-sided supply to power the component, but most signals are provided a bipolar fashion. To establish the center code for the ADC, a common-mode voltage (V_{CM}) may be defined between the two inputs. The common-mode voltage is the center point (e.g., relative zero) around which the signals fluctuate (e.g., symmetrically). Typically, the voltage at the common terminal of the ADC may be set to the common-mode voltage relative to which the input signals are applied.

In many ADCs, two arrays of capacitors, called PDAC and NDAC, may be used, that are coupled to positive and negative inputs, respectively, of the comparator. The common terminal (top plates) of the PDAC capacitors and the NDAC capacitors can be selectively coupled to the positive (in case of PDAC) or negative (in case of NDAC) terminals of the comparator or to V_{DD} (common-mode voltage V_{CM}) or ground (V_{SS}); the other terminal (bottom plates) of the PDAC capacitors and the NDAC capacitors are connected to switches (or a control signal) by which they can be selectively coupled to V_{IN}, V_{REF} or ground.

Typically, the PDAC and NDAC include a coupling capacitor that divides them into two spans. The bottom plate of each capacitor of the first span (also called the main DAC) of the PDAC is coupled to the switches that can selectively drive the bottom plates to V_{IN}, V_{REF} or ground. The bottom plates of the second span (also called the sub DAC) of the PDAC are coupled by switches to V_{REF} or ground. In case of the NDAC, the bottom plates of the first span and the second span of the NDAC are coupled by switches to V_{IN}, V_{CM}, V_{REF} or ground (e.g., in case of singled ended SAR ADCs or differential SAR ADCs). During sampling phase, the bottom plates of the main DAC are connected to V_{IN} and the top plates are connected to V_{CM}. During the bit-trial phase, the top plate of each capacitor is connected to the comparator in turn, and the bottom plates are connected to ground.

### Overview

The present disclosure relates generally to a passive analog sample and hold in analog-to-digital converters. In an example embodiment, an analog to digital converter (ADC) facilitating passive analog sample and hold is provided and includes a pair of binary weighted conversion capacitor arrays, a pair of sampling capacitors, and a plurality of switches that configure each conversion capacitor array and the sampling capacitors for a sampling phase, a charge transfer phase, and a bit trial phase. During the sampling phase, the sampling capacitors are decoupled from the conversion capacitors and coupled to an analog input voltage. During the charge transfer phase, the sampling capacitors are coupled to the conversion capacitors and decoupled from the analog input voltage. During the bit trial phase, the sampling capacitors are decoupled from the conversion capacitors. In specific embodiments, a sampling capacitance (Cs) of the sampling capacitors is a multiple of a conversion capacitance (Cd) of the conversion capacitors, the multiplier being greater than 1 (Cs=N×Cd, N>1).

### BRIEF DESCRIPTION OF THE DRAWINGS

FIG. 1 is a simplified block diagram illustrating an example schematic of a system to facilitate passive analog sample and hold in analog-to-digital converters;

FIGS. 2A-2C are simplified circuit diagrams illustrating example details of an embodiment of the system;

FIG. 3 is a simplified circuit diagram illustrating yet other example details of an embodiment of the system;

FIG. 4 is a simplified diagram illustrating yet other example details of an embodiment of the system;

FIG. 5 is a simplified circuit diagram illustrating yet other example details of an embodiment of the system;

FIG. 6 is a simplified block diagram illustrating yet other example details of an embodiment of the system;

FIG. 7 is a simplified diagram illustrating yet other example details of an embodiment of the system;

FIG. 8 is a simplified flow diagram illustrating example operations that may be associated with an embodiment of the system;

FIGS. 9A to 9F are simplified circuit diagrams illustrating example details of an embodiment of the system;

FIGS. 10A to 10F are simplified circuit diagrams illustrating other example details of an embodiment of the system; and

FIG. 11 is a simplified flow diagram illustrating yet other example operations that may be associated with an embodiment of the system;

### DESCRIPTION OF EXAMPLE EMBODIMENTS OF THE DISCLOSURE

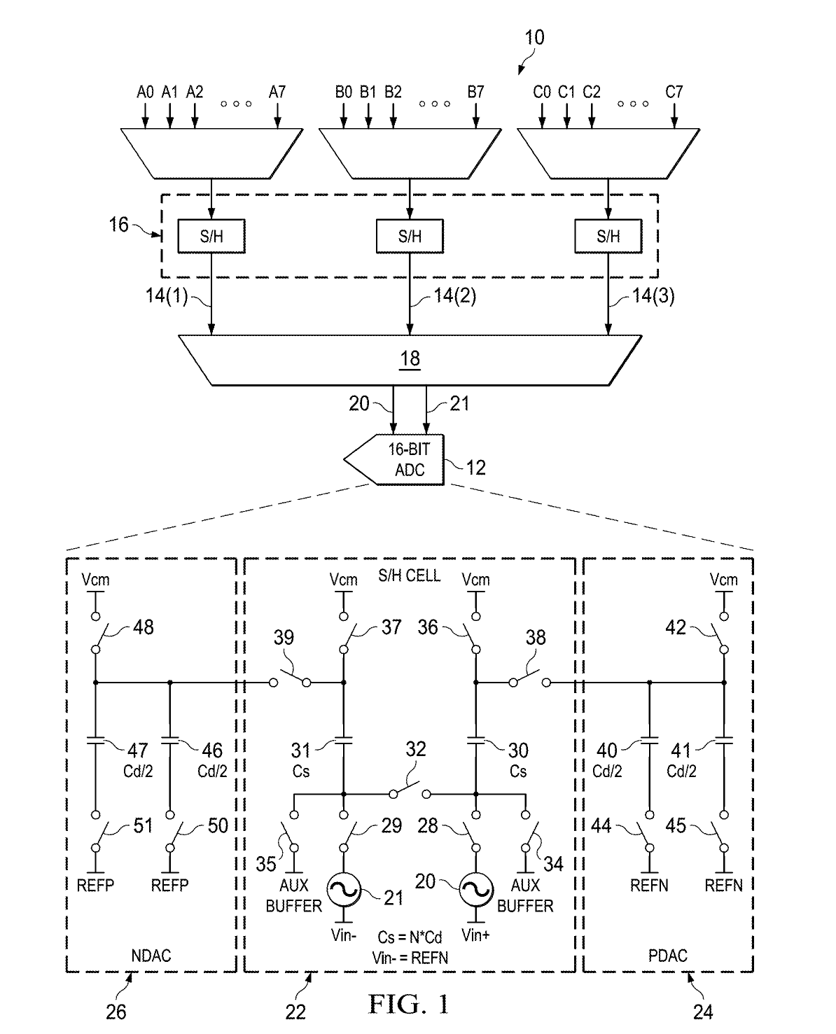

FIG. 1 is a simplified block diagram illustrating a system 10 comprising an ADC 12 that receives multiplexed samples from a plurality of channels (e.g., 14(1)-14(3)). A series of sample and hold (S/H) circuits 16 and a multiplexer 18 coupled to ADC 12 can be fabricated to use low area with reduced complexity. Multiplexer 18 is connected to ADC 12 at analog input terminals 20 (at V_{IN}+) and 21 (at V_{IN}−). In some embodiments, V_{IN}− may be set to a negative potential (REFN) of a reference voltage (V_{REF}). An example ADC 12 can convert three simultaneously sampled channels 14(1)-14(3) (e.g., one each from Ax, Bx and Cx). In an example embodiment, ADC 12 may comprise a successive approximation register (SAR) ADC. In some embodiments, ADC 12 may comprise a simultaneous sampling SAR ADC.

A portion of ADC 12 and S/H circuits 16 is shown in greater detail in the figure. ADC 12 and S/H circuits 16 include a sample and hold (S/H) cell 22, a PDAC 24, and a NDAC 26 (e.g., S/H cell 22 may belong to S/H circuit 14; PDAC 24 and NDAC 26 may belong to ADC12). S/H cell 22 is connected to analog input lines 20 (V_{IN}+) and 21 (−V_{IN}−). Input switches 28 and 29 selectively connect respective input lines 20 and 21 to bottom plates of sampling capacitors 30 and 31, each having capacitance Cs. Bottom plates of sampling capacitors 30 and 31 can also be selectively connected to each other by discharge switch 32. Bottom plates of sampling capacitors 30 and 31 can also be selectively connected to auxiliary buffers (not shown) by auxiliary switches 34 and 35, respectively. Top plates of sampling capacitors 30 and 31 can be selectively connected by respective S/H common-mode switches 36 and 37 to a common terminal at common-mode voltage V_{CM}. Top plates of sampling capacitors 30 and 31 can be selectively connected by respective decoupling switches 38 and 39 to PDAC 24 and NDAC 26.

PDAC 24 includes conversion capacitors 40 and 41, each having capacitance Cd/2 for a total conversion capacitance of Cd. In various embodiments, the sampling capacitance Cs is configured to be N times the conversion capacitance Cd(Cs=N×Cd), where N is any positive number (e.g., greater than 1 in some embodiments). The top plates of conversion capacitors 40 and 41 can be connected by decoupling switch 38 to the top plate of sampling capacitor 30. The top plates of conversion capacitors 40 and 41 can also be connected by DAC common-mode switch 42 to the common terminal at common-mode voltage V_{CM}. The bottom plates of conversion capacitors 40 and 41 are connected to a positive (REFP) and negative (REFN) reference voltage V_{REF}, respectively, by respective reference switches 44 and 45.

NDAC 26 includes conversion capacitors 46 and 47, each having capacitance Cd/2. The top plates of conversion capacitors 46 and 47 can be connected by decoupling switch 39 to the top plate of sampling capacitor 31. The top plates of conversion capacitors 46 and 47 can also be connected by DAC common-mode switch 48 to the common terminal at common-mode voltage V_{CM}. The bottom plates of conversion capacitors 46 and 47 are connected to a positive (REFP) and negative (REN) reference voltage V_{REF}, respectively, by respective reference switches 50 and 51. Note that each capacitor shown in the figure can comprise an array of a plurality of capacitors in some embodiments, with effective capacitance as indicated in the FIGURE (e.g., Cs, Cd/2).

Some currently existing devices use a driver amplifier, such as a pre charge buffer, to convert single ended inputs to differential inputs for improving the input signal swing going to the ADC, thereby improving the signal power. Such devices have two 16 bit ADCs sampling directly to the conversion DAC of the ADC. If such devices have one pre-charge buffer per multiplexed output and one dedicated ADC per multiplexed output, increasing signal power may come with certain advantages. However, there may be an additional cost in terms of additional power consumed in the pre-charge buffers. Where three inputs from multiplexers are subjected to sample and hold with conversion one by one by a single 16 bit ADC, there can be a 50% charge sharing loss when transferring the signal from the sampling capacitors to the ADC irrespective of whether a pre-charge buffer is present. The pre charge buffers can be power hungry.

In a pre-buffer amplifier architecture, a pre-buffer amplifier connects to the bottom plates of the sampling capacitors of the S/H cell. The sampling capacitance (Cs) is equal to the conversion capacitance (Cd). In the sampling phase in such architecture, the pre-buffer amplifier receives the analog input voltage and charges the sampling capacitors, which are decoupled from the conversion capacitors of the PDAC and NDAC. At the end of the sampling phase, the sampling capacitors are decoupled from the input and coupled to the conversion capacitors on the top plates (the bottom plates being connected to ground). The charge stored in the sampling capacitors are discharged and shared between the sampling capacitors and the conversion capacitors. The differential voltage at the comparator in the discharge step is −V_{IN}/2+V_{REF}/4. Thus, such pre-buffer amplifier architecture can have an attenuation of ½ and further, the reference voltage may be attended with time varying noise, which can negatively impact the ADC's accuracy.

Traditional ADC architectures require that the input common-mode voltage should not be more than 50 mV to 100 mV different from V_{REF}/2. This is as a result of the traditional way of sampling the input signal and converting it on the same capacitor DAC (conversion DAC) along with the limited common-mode range of the comparator used in the ADCs. In some embodiments of system 10, the input signal is sampled on to a different set of capacitors (sampling DAC) and is coupled to the conversion DAC by connecting the top plates of the two DACs together and shorting the bottom plates of the sampling DAC to transfer the differential signal and block the input common-mode voltage on the sampling capacitors. However the V_{REF} and V_{IN} are scaled, potentially affecting the maximum signal swing and signal-to-noise ratio (SNR). For example, the signal swing can be attenuated by ½, also reducing the SNR. Further, the reference may also be attenuated by ½, thereby reducing the quantization noise and the maximum signal swing that can be converted by the ADC.

Turning back to system 10, unlike ADCs currently in market or ADCs with pre-buffer amplifiers, embodiments of system 10 can offer a passive sample and hold scheme with no additional noise added. The architecture of ADC 12 can decouple the input and reference attenuation factors and reduces the input signal attenuation as well as the reference attenuation. The sample and hold scheme includes integral nonlinearity (INL) compensation for making the circuit insensitive to nonlinear parasitic capacitors. In various embodiments, the high swing, low noise ADC 12 can convert maximum input signal of ±2×V_{REF} with a reference voltage of V_{REF}. ADC 12 can have independent sample and hold for better acquisition time without compromising much on the speed due to pipe-lining. Further, an additional charge transfer phase is required compared to other (e.g., conventional; currently in market) ADCs. Embodiments of system 10 can be well suited for simultaneously sampled multiplexed ADCs where signal attenuation due to charge sharing is a concern. Embodiments of system 10 can decouple the signal attenuation from reference attenuation and maximize the differential charge transfer from sampling capacitors 30 and 31 to conversion capacitors 40, 41, 46 and 47.

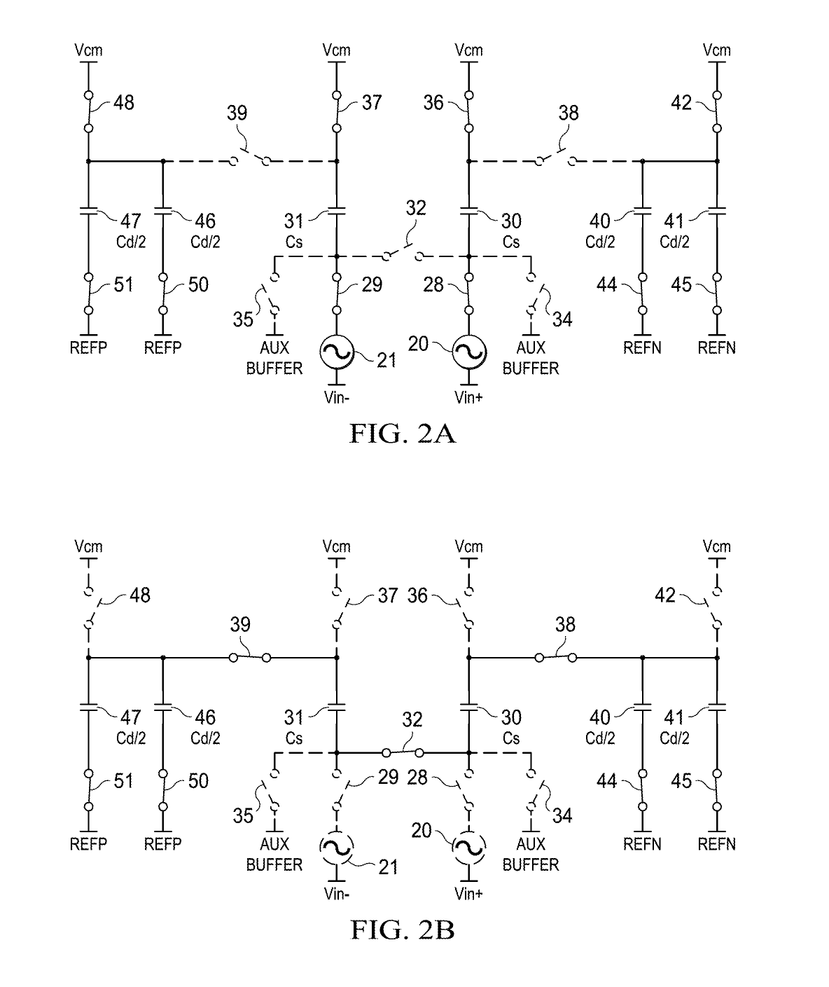

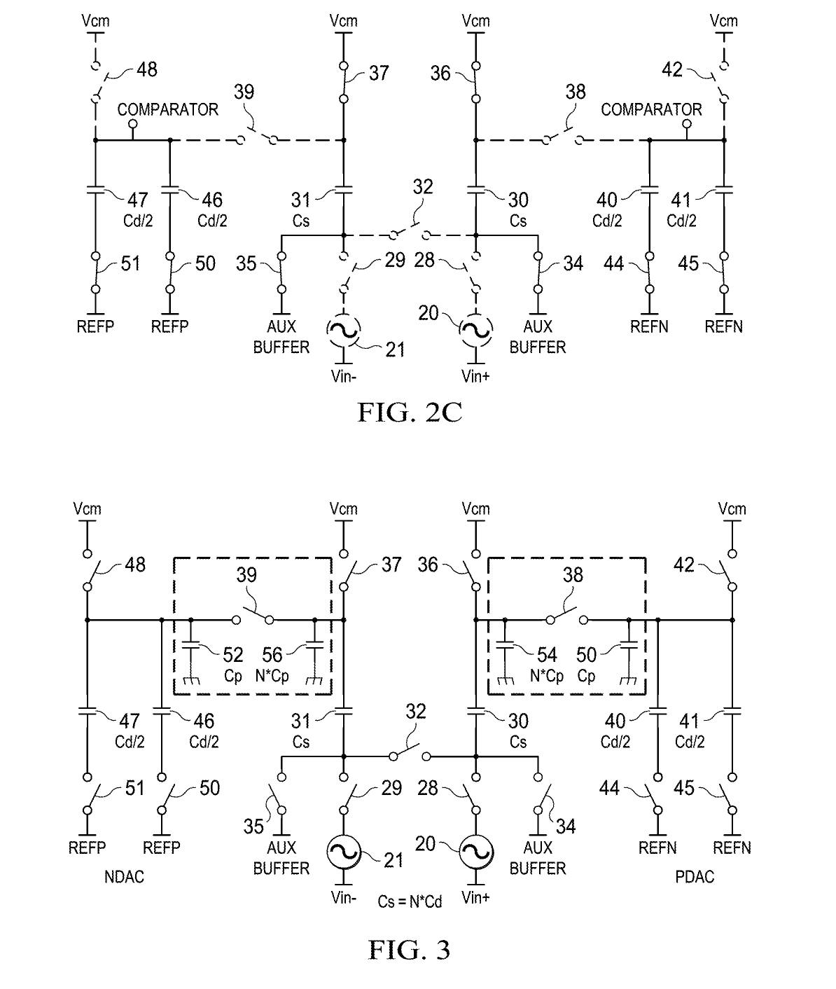

Turning to FIGS. 2A-2C, FIGS. 2A-2C are simplified circuit diagrams showing details of operation of an embodiment of system 10. Note that inactive portions of the circuit are shown in dotted lines merely for ease of description. In FIG. 2A, the sampling phase is shown, with input switches 28 and 29 and S/H common-mode switches 36 and 37 being closed and discharge switch 32, auxiliary switches 34 and 35, and decoupling switches 38 and 39 being open. Sampling capacitors 30 and 31 are charged by inputs 20 (V_{IN}+) and 21 (V_{IN}−) and are decoupled from PDAC 24 and NDAC 26.

At the end of the sampling phase, the top plates of sampling capacitors 30 and 31 are disconnected by opening S/H common-mode switches 36 and 37, as indicated in FIG. 2B. Sampling capacitors 30 and 31 are decoupled from inputs 20 (V_{IN}+) and 21 (V_{IN}−) by opening input switches 28 and 29. The top plates of sampling capacitor 30 and conversion capacitors 40 and 41 are shorted by closing decoupling switch 38; likewise, the top plates of sampling capacitors 31 and conversion capacitors 46 and 47 are shorted by closing decoupling switch 39. Reference switches 44, 45, 51, 50 and discharge switch 32 are closed, completing the discharge circuit, and the charge stored by sampling capacitors 30 and 31 are shared between sampling capacitors 30 and 31 and conversion capacitors 40, 41, 46 and 47. Note that when discharge switch 32 is closed, the bottom plates of sampling capacitors 30 and 31 are shorted, reducing the voltage swing at the top plate, allowing differential bit trials (with potential reference noise cancellation) and blocking the common-mode voltage. For example, the reference noise is canceled as the bit trials are performed differentially (e.g., as in differential ADC) compared to conventional ADCs. Shorting of the bottom plates of sampling capacitors 30 and 31 can ensure that the common mode voltage is rejected. In some embodiments, instead of shorting the bottom plates of sampling capacitors 30 and 31, the bottom plates may be connected to fixed voltages (e.g., V_{REF}/2).

In FIG. 2C, in preparation for the bit trial phase, decoupling switches 38 and 39 are opened, decoupling PDAC 24 and NDAC 26 from sampling capacitors 30 and 31. The top plates of PDAC 24 and NDAC 26 are subsequently connected to a comparator (not shown). Sampling capacitors 30 and 31 are pre-charged to a voltage close to V_{IN} by closing auxiliary switches 34 and 35 and S/H common-mode switches 36 and 37 to reset for the next sampling phase.

Unlike ADCs currently in market or ADCs with pre-buffer amplifiers, because the sampling capacitance Cs is equal to N times the conversion capacitance, the signal attenuation is reduced during differential charge transfer phase of FIG. 2B, thereby improving SNR. Note that in ADCs currently in market or ADCs with pre-buffer amplifiers, the top plate of the sampling capacitors are connected, thereby involving sampling capacitance Cs in the bit trial phase. Hence, the Cs cannot be made larger than Cd, as it attenuates the reference even further than 50%. Moreover, unlike ADCs with pre-buffer amplifiers, because the sampling capacitors are disconnected from the conversion capacitors during bit trial phase in ADC 12, top plate switches 38 and 39 are present in various embodiments of ADC 12. Further, embodiments of system 10 can block the common-mode voltage V_{CM} from reaching the top plate of the conversion capacitors, which comprise inputs of the comparator. Hence, embodiments of system 10 can support rail to rail input common-mode voltages. One particular embodiment of system 10 can give ±2V_{REF} differential swing and 0 to 2V_{REF} common-mode range. Various embodiments of system 10 include an additional “Charge Transfer” phase wherein charge is transferred from sampling capacitors 30 and 31 to conversion capacitors 40, 41, 46 and 47 and various switches are opened between sampling and bit trial phases.

Because the total sampling capacitance Cs is N times conversion capacitance Cd, an external driver such as the auxiliary buffer can charge the large sampling capacitors 30 and 31. In various embodiments, an auxiliary buffer or amplifier may be used to pre-charge the sampling capacitors 30 and 31 to a voltage close to the input voltage V_{IN} before introducing external inputs 20 and 21 to sampling capacitors 30 and 31 so that the charge taken from external inputs 20 and 21 is minimized.

In various embodiments, during the bit trial phase, sampling capacitors 30 and 31 are decoupled from conversion capacitors 40, 41, 46 and 47 and coupled to another channel (or the same channel) of the analog input voltage, thereby starting the sampling phase of a next cycle. In some embodiments, during charge transfer phase of a first set of inputs (e.g., channel A), another sampling phase may be started for a next set of inputs (e.g., channel B), while the bit trial phase of a third set of inputs (e.g., channel C) may be performed concurrently, reducing the overall time required for the three inputs. In case of multiplexed inputs, the analog input voltage during the bit trial phase (and sampling phase of the next cycle) can correspond to another input channel. In embodiments in which the same channel is converted repeatedly, the analog input voltage may be same as that used in the sampling phase of the current cycle.

Turning to FIG. 3, FIG. 3 is a simplified circuit diagram illustrating example details of an embodiment of system 10. Assume, merely for example purposes, and not as a limitation, that a parasitic capacitance Cp is present at the top plate of sampling capacitors 30 and 31, where Cp is a function of voltage on the top plate node. The parasitic capacitance may be introduced due to the junction capacitances of the MOS devices used to realize the switches. The parasitic capacitance on either side of decoupling switches 38 and 39 may be trimmed for integral non-linearity (INL) compensation (e.g., to compensate for process related mismatches in switch sizes, affecting capacitance).

According to various embodiments, a trimming mechanism may use dummy switches tied to either side of decoupling switches 38 and 39. In various embodiments, the dummy switches may comprise MOS capacitors with their source and drain shorted and a control signal (e.g., logic HIGH/LOW) applied to the gate terminal. The capacitance for a PMOS capacitance is lower when the gate terminal is tied to a high voltage so that the dummy switch is in an OFF position than when the gate terminal is tied to a low voltage so that the dummy switch is in an ON position. Likewise, the capacitance for a NMOS capacitance is lower when the gate terminal is tied to a low voltage so that the dummy switch is in an OFF position than when the gate terminal is tied to a high voltage so that the dummy switch is in an ON position. Thus, a parasitic capacitor can be introduced whose capacitance can be varied by applying a digital signal at the gate of the dummy switch. Such mechanism also helps in compensating for errors due to charge injection from decoupling switches 38 and 39 when they are turned OFF at the end of the charge transfer phase.

To describe in more detail, the sampled voltage may experience an attenuation of roughly Cs/[Cs+Cd+Cp], whereas the reference voltage may experience an attenuation of Cd/[Cd+Cp], potentially leading to gain error dependent on Cp, and Cp in turn depends on the input sampled voltage. Thus, the parasitic capacitance can lead to nonlinearity proportional to the absolute value of Cp present on the top plate of PDAC 24 and NDAC 26. In equation form, the top plate voltage after charge dump and during the first bit trial phase is:

$$\begin{matrix}{V}_{x , p} = {V}_{CM} - {V}_{IN} \frac{Cs}{[ Cs + Cd + Cp ]} + \frac{1}{2} {V}_{REF} \frac{Cd}{[ Cd + Cp ]} \\ = {V}_{CM} - \frac{Cd}{[ Cd + Cp ]} \{ {V}_{IN} \frac{Cs}{Cd} \frac{[ Cd + Cp ]}{[ Cs + Cd + Cp ]} - \frac{1}{2} {V}_{REF} \}\end{matrix}$$

The scaling factor of V_{IN}, namely

$$\frac{Cs}{[ Cs + Cd ]} \frac{[ 1 + \frac{Cp}{Cd} ]}{[ 1 + \frac{Cp}{( Cs + Cd )} ]}$$

is approximately equal to

$$\frac{Cs}{[ Cs + Cd ]} [ 1 + \frac{Cp ( v )}{Cd} - \frac{Cp ( v )}{Cs + Cd} ] ,$$

where Cp(v) is a voltage dependent term, which can lead to INL. INL may be correctable by digital trimming. However, trimming a parameter that depends on the absolute value of parasitic capacitance can be challenging. For example, capacitance can vary with temperature and supply voltage (V_{DD}), and trimming for the absolute parasitic capacitance may not be a feasible solution under such environmentally varying conditions.

According to embodiments of system 10, a voltage dependent parasitic capacitor is introduced during sampling that can be removed during bit trials. In various embodiments, a ratio of the intentionally introduced parasitic capacitance to the top plate parasitic capacitance is in the same ratio as Cs:Cd (e.g., N), whereby the nonlinear gain terms may be forced to disappear. To illustrate further, assume that parasitic capacitance of the conversion DAC top plate can be represented by capacitors 50 and 52 (on PDAC 24 and NDAC 26, respectively), having capacitance Cp. According to embodiments of system 10, INL compensation capacitors 54 and 56 (on PDAC side and NDAC side, respectively), may be introduced in S/H cell 20. Note that Cp=Cp₀(1+kVc) . . . , where Vc is the voltage across the parasitic capacitance. Only the first order coefficient is used, and higher order (e.g., quadratic) terms are disregarded for ease of description.

During the sampling phase, the total charge stored on sampling capacitors 30 and 31 and conversion capacitors 40 and 41 of PDAC 24 is given below:

$${Q}_{init} = ( {V}_{CM} - {V}_{{IN}_{CM}} - {V}_{{IN}_{DM}} ) Cs + {V}_{CM} [ Cd + {Cp}_{d 0} ( 1 + {kV}_{CM} ) + {Cp}_{s 0} ( 1 + {kV}_{CM} ) ] = {V}_{CM} [ Cs + Cd + {Cp}_{s 0} ( 1 + {kV}_{CM} ) + {Cp}_{d 0} ( 1 + {kV}_{CM} ) ] - ( {V}_{{IN}_{CM}} + {V}_{{IN}_{DM}} ) Cs$$

where Cp_{d} is the parasitic capacitance and Cpₛ is the INL compensation capacitance. Note that according to certain embodiments, any mismatches between the ratios Cs/Cd and Cpₛ/Cp_{d} can be trimmed by adding additional capacitance on Cs or Cd. The total charge on PDAC 24 top plate after charge transfer phase from sampling capacitors 30 and 31 to bit trial phase is given by:

Q_{ct}=Vx[Cs+Cd+Cpₛ₀(1+kV_{CM})+Cp_{d0}(1+kV_{CM})]−V_{IN}_{_{CM}}Cs

where Vx is the voltage at the top plate at the end of charge transfer. From the above equations, Vx can be derived as follows:

$$Vx = \frac{{V}_{CM} [ Cs + Cd + {Cp}_{s 0} ( 1 + {kV}_{CM} ) + {Cp}_{d 0} ( 1 + {kV}_{CM} ) ]}{[ Cs + Cd + {Cp}_{s 0} ( 1 + {kV}_{x} ) + {Cp}_{d 0} ( 1 + {kV}_{x} ) ]} - {V}_{{IN}_{DM}} \frac{Cs}{[ Cs + Cd + {Cp}_{s 0} ( 1 + {kV}_{x} ) + {Cp}_{d 0} ( 1 + {kV}_{x} ) ]}$$

If Cpₛ/Cp_{d}=Cs/Cd; Cs=N×Cd, then Cpₛ=NCp_{d}. Thus, Vx can be further derived as follows:

$$Vx = \frac{{V}_{CM} [ ( N + 1 ) Cd + ( N + 1 ) {Cp}_{d 0} ( 1 + {kV}_{CM} ) ]}{[ ( N + 1 ) Cd + ( N + 1 ) {Cp}_{d 0} ( 1 + {kV}_{x} ) ]} - {V}_{{IN}_{DM}} \frac{NCd}{[ ( N + 1 ) Cd + ( N + 1 ) {Cp}_{d 0} ( 1 + {kV}_{x} ) ]}$$

$$Thus , Vx = \frac{{V}_{CM} [ Cd + {Cp}_{d 0} ( 1 + {kV}_{CM} ) ]}{[ Cd + {Cp}_{d 0} ( 1 + {kV}_{x} ) ]} - {V}_{{IN}_{DM}} \frac{\frac{N}{N + 1} Cd}{[ Cd + {Cp}_{d 0} ( 1 + {kV}_{x} ) ]}$$

$$If {V}_{CM} = 0 , Vx [ Cd + {Cp}_{d 0} ( 1 + {kV}_{x} ) ] = - {V}_{{IN}_{DM}} \frac{N}{N + 1} Cd .$$

Thus, charge on 1/N of the total capacitor (split and used for charge redistribution) has a charge equal to

$$- {V}_{{IN}_{DM}} \frac{N}{N + 1} Cd ,$$

which can be used to start the charge redistribution ADC 12. In other words, the initial charge on the conversion DAC is proportional to the input voltage. Moreover, with capacitors 54 and 56 it may easier to trim the INL for mismatch rather than absolute variation of top plate parasitic capacitance.

In various embodiments, the voltage dependent parasitic capacitor is introduced using dummy switches. A number and/or size of dummy switches in ADC 12 may be configured to match the parasitic capacitance of the conversion capacitor arrays and the sampling capacitors according to the multiplier relationship (e.g., N) between the sampling capacitance Cs and the conversion capacitance Cd. For example, N dummy switches may be introduced appropriately in S/H cell 20 to match parasitic capacitances in PDAC 24 with suitable trimming as desired. As described previously, the dummy switch capacitance in a closed configuration may have 50% lower capacitance compared to the open configuration, facilitating an option to trim the INL in case of mismatches. In an example embodiment, the trimming may be achieved by trimming bits on the conversion capacitance Cd side of the circuit (e.g., capacitors 50; 52) relative to decoupling switches 38 and 39 to increase the Cp_{d}/Cpₛ ratio; and by trimming bits on the sampling capacitance Cs side of the circuit (e.g., capacitors 54, 56) to decrease the Cp_{d}/Cpₛ ratio.

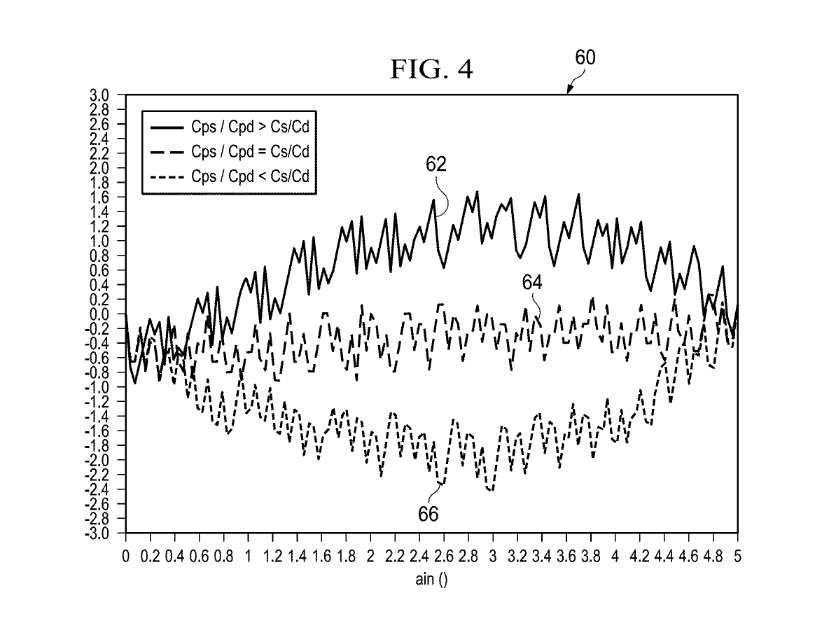

Turning to FIG. 4, FIG. 4 is a simplified graph 60 illustrating simulated INL error varying with input voltage according to embodiments of system 10. The INL error in 16 bit LSBs is plotted on the Y-axis, and input voltage is plotted along the X-axis. Plot 62 indicates the case where Cs/Cd=4 and Cpₛ/Cp_{d}=5 (Cpₛ/Cp_{d}>Cs/Cd). Plot 64 indicates the case where Cs/Cd=4=Cpₛ/Cp_{d}. Plot 66 indicates the case where Cs/Cd=4 and Cpₛ/Cp_{d}=3 (Cpₛ/Cp_{d}<Cs/Cd). INL error is closest to zero when Cs/Cd=Cpₛ/Cp_{d}. Note that for a 20% mismatch in parasitic capacitance at top plate INL is 2.5LSB at 16 bits.

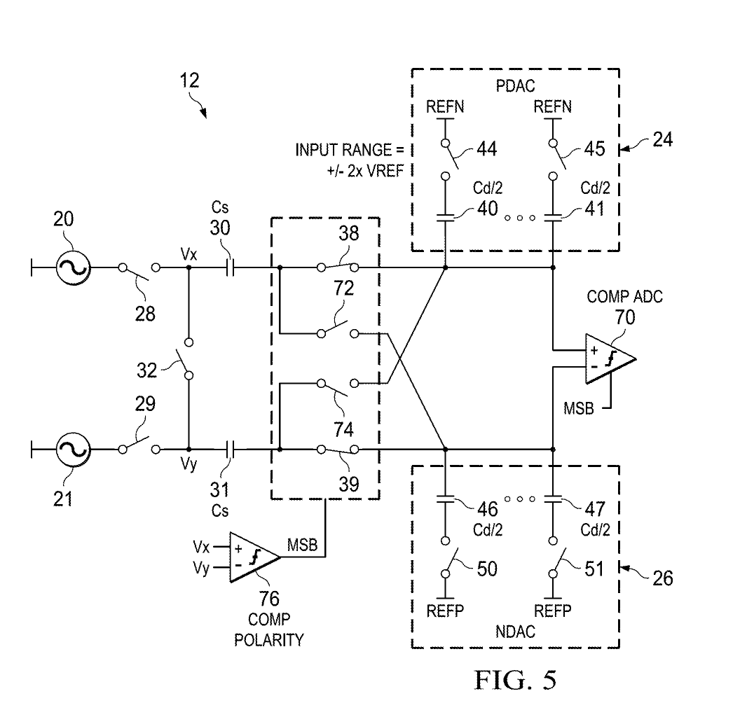

Turning to FIG. 5, FIG. 5 is a simplified circuit diagram illustrating another embodiment of system 10 included in a large swing ADC. ADC 12 includes a comparator 70 connected to PDAC 24 on its positive terminal and to NDAC 26 on its negative terminal. ADC 12 includes sampling capacitors 30, 31 and conversion capacitors 40 and 41 in PDAC 24, and 46 and 47 in NDAC 26. ADC 12 includes, in addition to switches 28, 29, 32, 38, 39, 44, 45, 50 and 51, additional decoupling switches 72 and 74 that can selectively change connections of sampling capacitors 30 and 31 to PDAC 24 and NDAC 26, for example, depending on inputs Vx and Vy to a polarity comparator 76.

After the sampling phase, input switches 28 and 29 are opened, and discharge switch 32 is closed. Thereupon, voltages at points vx and vy change to the common-mode voltage V_{CM} of V_{IN}/2. When decoupling switches 38 and 39 are closed and V_{REF} is applied to PDAC 24 and NDAC 26 in the bit trial phase, the input voltage at comparator 70 is V_{CM}− (V_{IN}/2)×Cs/(Cs+Cd)+V_{REF}×Cd/(Cs+Cd) at the positive terminal, and V_{CM}+(V_{IN}/2)×Cs/(Cs+Cd) at the negative terminal. Thus, if sampling capacitors stay connected to PDAC 24 and NDAC 26 during the bit trial phase, V_{REF} must be equal to V_{IN}/2 to avoid saturation; in other words, V_{IN} can vary as much as ±V_{REF}. On the other hand, if sampling capacitors 30 and 31 are decoupled from PDAC 24 and NDAC 26 after the charge transfer phase by opening decoupling switches 38 and 39, the voltage at the positive terminal of comparator 70 during the bit trial phase is V_{CM}− (V_{IN}/2)×CS/(CS+Cd)+V_{REF}; and the voltage at the negative terminal of comparator 70 is V_{CM}+(V_{IN}/2)×Cs/(Cs+Cd)−V_{REF}. Thus, V_{IN} can vary as ±2V_{REF} and avoid saturation.

According to various embodiments, the sample and hold mechanism described herein decouples the input attenuation from the reference attenuation, enabling a new architecture that can convert ±2V_{REF} signal using V_{REF}. For example, the sampling scheme enables a converter to sample ±5V (e.g., 10V peak to peak signal) and convert it using a 2.5V reference. Thus, the reference noise can be reduced by one half when compared to traditional ADCs that require 5V reference to convert a ±5V signal.

In various embodiments, polarity comparator 76 may be used to determine which of switches 38, 39, 72 and 74 to be closed (or open). For example, input voltage may be applied on Vx and Vy at polarity comparator 76. Substantially simultaneously they may be sampled on to low accuracy comparator 76, with error less than redundancy range of ADC 12. Based on the polarity comparator decision of polarity comparator 76, if Vx>Vy, switch 72 is opened, switch 38 is closed to charge dump sampling capacitor 30 onto PDAC 24 and switch 74 is opened, switch 39 is closed to charge dump sampling capacitor 31 onto NDAC 26; otherwise, if Vx<Vy, switch 72 is closed, switch 38 is opened to charge dump sampling capacitor 30 onto NDAC 26 and switch 74 is closed, switch 39 is opened to charge dump sampling capacitor 31 onto PDAC 24. Thus, the top plates experience a swing of ±2V_{REF}. For example, a 10y peak to peak signal can be converted with 2.5V reference voltage.

The charge transfer may be allowed to settle to ADC accuracy and sampling capacitors 30 and 31 may be decoupled thereafter. Subsequently, bit trials may be started. In some embodiments, ADC comparator 70 may be reused as polarity comparator 76. To implement ±V_{REF} (rather than ±2V_{REF}) input range ADC, half the capacitors (e.g., 40 and 46 in PDAC 24 and NDAC 26, respectively) may be connected to REFP (positive V_{REF}) and the other half (e.g., 41 and 47 in PDAC 24 and NDAC 26, respectively) may be connected to REFN (negative V_{REF}), so that the top plates have a swing of ±V_{REF}/2.

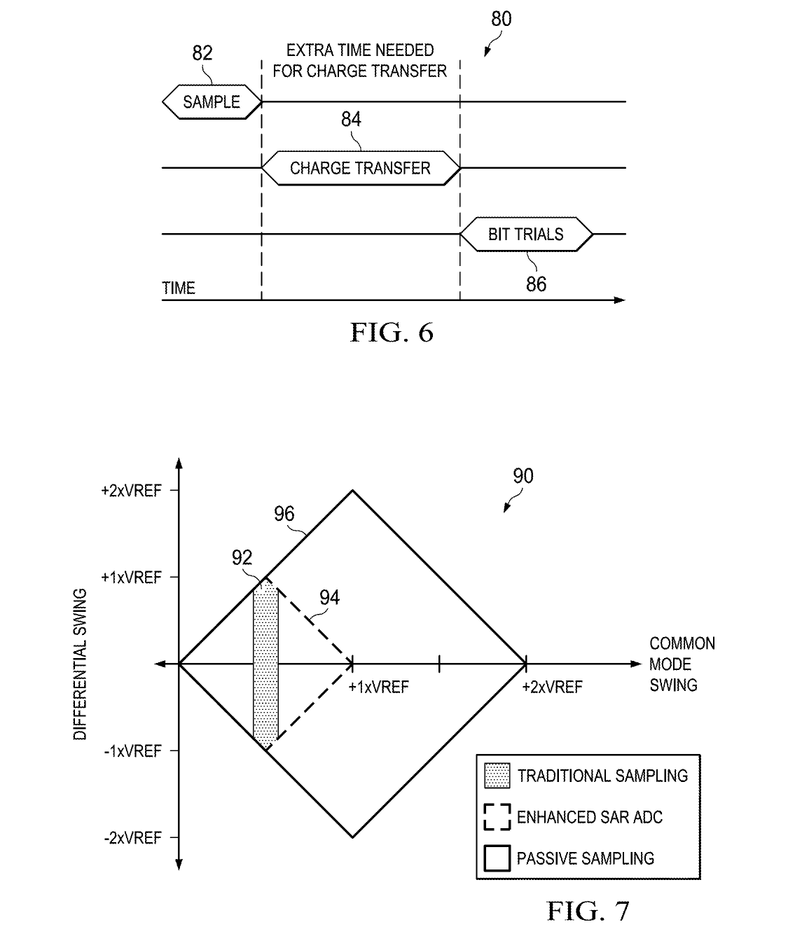

Turning to FIG. 6, FIG. 6 is a simplified block diagram illustrating an example timing sequence 80 of an embodiment of system 10. At least three distinct phases may be present in the sample and hold scheme according to various embodiments. In sample phase 82, input current may charge sampling capacitors 30 and 31. In subsequent charge transfer phase 84, charge may be distributed from sampling capacitors 30 and 31 to conversion capacitors 40 and 41 in PDAC 24 and 46 and 47 in NDAC 26. Subsequently, in bit trial phase 86, conversion capacitors 40, 41, 46 and 47 may be input to a comparator (e.g., 70) to determine the digital code corresponding to the analog input.

According to various embodiments of ADC 12, longer time than in typical ADCs may be required to complete charge transfer phase 84. The longer time may be at least due to the time required to transfer the differential charge to the conversion DACs (PDAC 24 and NDAC 26) to the accuracy of ADC 12, before disconnecting sampling capacitors 30 and 31. In some embodiments, the sample and hold scheme may be used in conjunction with a pipe-lined SAR architecture to speed up the pipelining process and reduce impact of longer charge transfer phase 84. Thus, during charge transfer phase 84 of a first set of inputs (e.g., channel A), sampling phase 82 may be started for the next set of inputs (e.g., channel B), while bit trial phase 86 of a third set of inputs (e.g., channel C) may be performed concurrently in some embodiments, reducing the overall time required for the three inputs.

Turning to FIG. 7, FIG. 7 is a simplified graph 90 depicting the differential swing (on the Y-axis) with respect to the common-mode swing (on the X-axis) of an ADC for a fixed reference voltage V_{REF}. The differential swing indicates the range of differential analog input that can be supported by the ADC. Three different response patterns are depicted in graph 90—pattern 92 indicates the response pattern with traditional sampling (e.g., typical, customary, etc., without the sample and hold as described herein); pattern 94 indicates the response pattern with an enhanced SAR ADC that does not use the sample and hold as described herein; and pattern 96 indicates the response pattern for the passive sampling that uses the sample and hold as described herein.

Traditional sampling allows a differential input range of −V_{REF} to V_{REF}. However, the common-mode voltage can swing only in a small range (e.g., ±0.1V) around V_{REF}/2, as indicated by pattern 92. The enhanced SAR ADC supports unipolar, true-differential analog input signals with a differential input swing of −V_{REF} to V_{REF}. The true differential analog input structure (as indicated by pattern 94) apparently allows for a common-mode voltage of any value on the range of 0V to V_{REF}, offering a maximum dynamic range for V_{CM}=V_{REF}/2. On the other hand, the passive sampling scheme as described herein and indicated by pattern 96, allows an input range of −2V_{REF} to 2V_{REF}, and also allows the common-mode voltage swing of 0V to 2V_{REF}, offering a maximum dynamic range for VCM=V_{REF}. Note further that in the traditional sampling and enhanced SAR ADC, maximum differential input swing of ±V_{REF} is reached with V_{CM}=V_{REF}/2. On the other hand, with the passive sampling as described herein, maximum differential input swing of ±2V_{REF} is reached with V_{CM}=V_{REF}.

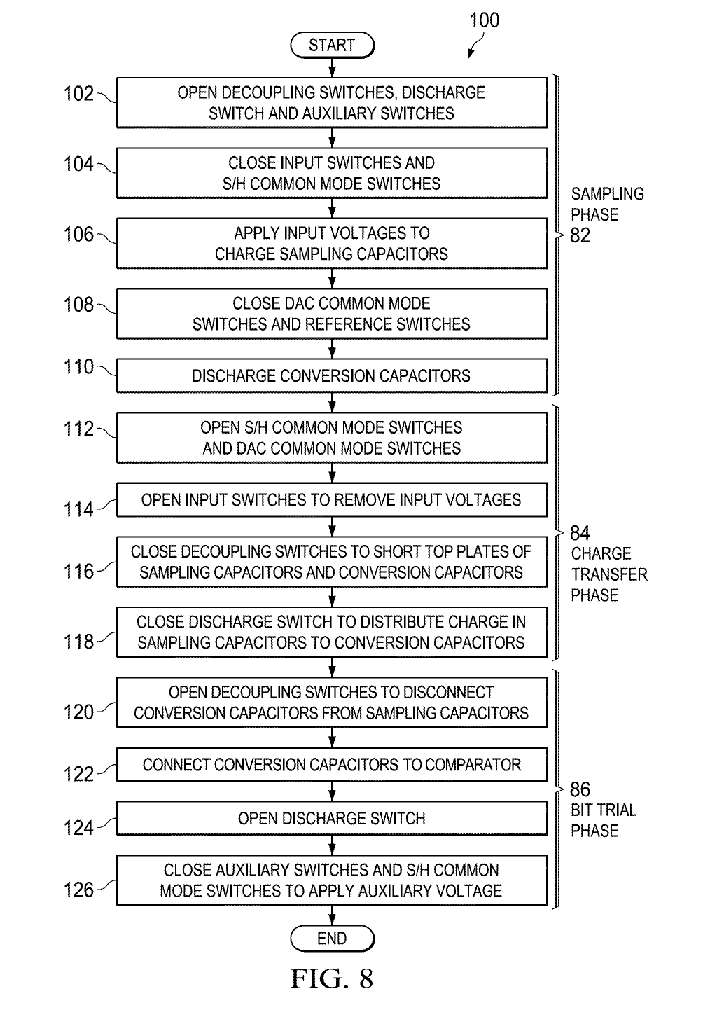

Turning to FIG. 8, FIG. 8 is a simplified flow diagram illustrating example operations 100 that may be associated with embodiments of system 10. At 102, decoupling switches 38 and 39, discharge switch 32, and auxiliary switches 34 and 35 are opened. At 104, input switches 28 and 29, and S/H common-mode switches 36 and 37 are closed. At 106, analog input voltage is applied at 20 and 21 to charge sampling capacitors 30 and 31. DAC common-mode switches 42 and 48, and reference switches 44, 45, 50 and 51 are closed at 108. At 110, conversion capacitors 40, 41, 46 and 47 are discharged. Operations 102 to 110 comprise sampling phase 82, at which the analog input voltage is acquired by ADC 12.

At 112, S/H common mode switches 36 and 37 and DAC common mode switches 42 and 48 are open. At 114, input switches 28 and 29 are opened to remove the analog input voltage at 20 and 21. At 116, decoupling switches 38 and 39 are closed to short top plates of sampling capacitors 30 and 31 to respective conversion capacitors {40, 41} and {46, 47}, respectively. At 118, discharge switch 32 is closed to distribute charge stored in sampling capacitors 30 and 31 during sampling phase 82 to conversion capacitors 40, 41, 46, and 47. Operations 112 to 118 comprise charge transfer phase 84, at which charges are transferred from sampling capacitors 30 and 31 to conversion capacitors 40, 41, 46, and 47.

At 120, decoupling switches 38 and 39 are opened to disconnect sampling capacitors 30 and 31 from conversion capacitors 40, 41, 46, and 47. At 122, conversion capacitors 40, 41, 46, and 47 may be connected to comparator 70, at which the analog input voltage, converted to stored charge on the capacitors, may be converted to digital code. At 124, discharge switch 32 may be opened. At 126, auxiliary switches 34 and 35, and S/H common-mode switches 36 and 37 may be closed to apply an auxiliary voltage on sampling capacitors 30 and 31. Operations 120-126 comprise bit trial phase 86, at which the analog input voltage is converted to digital code.

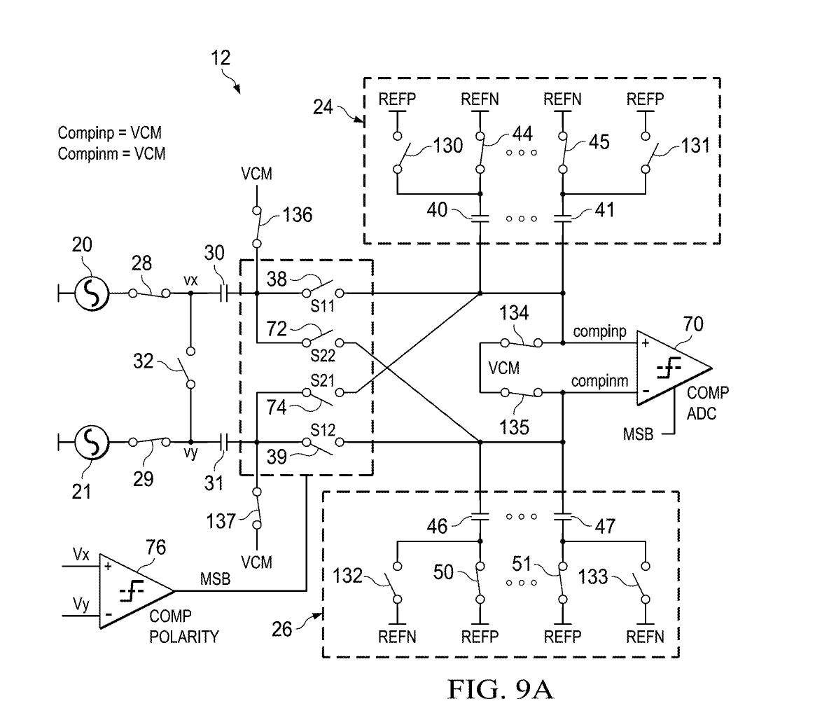

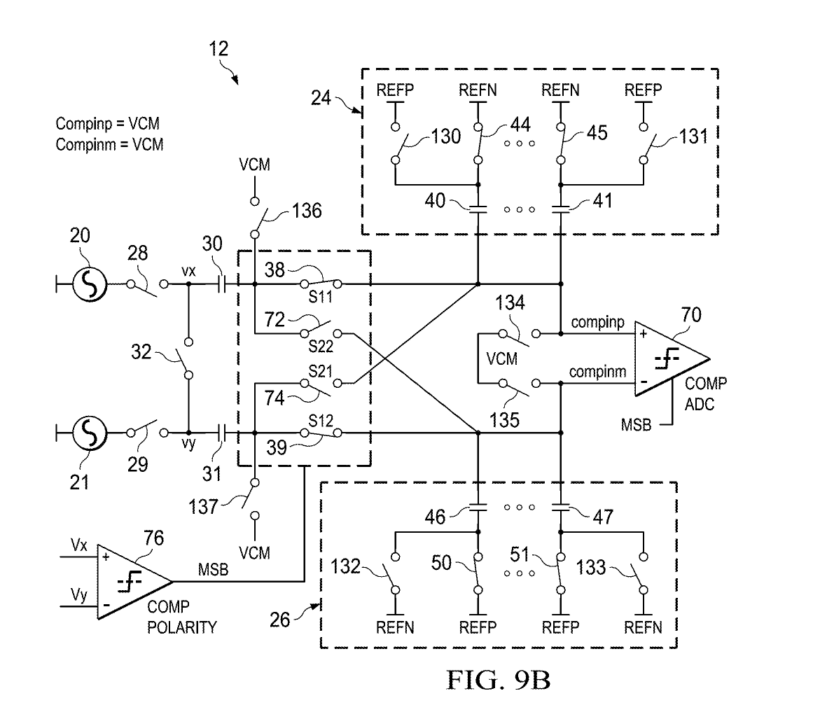

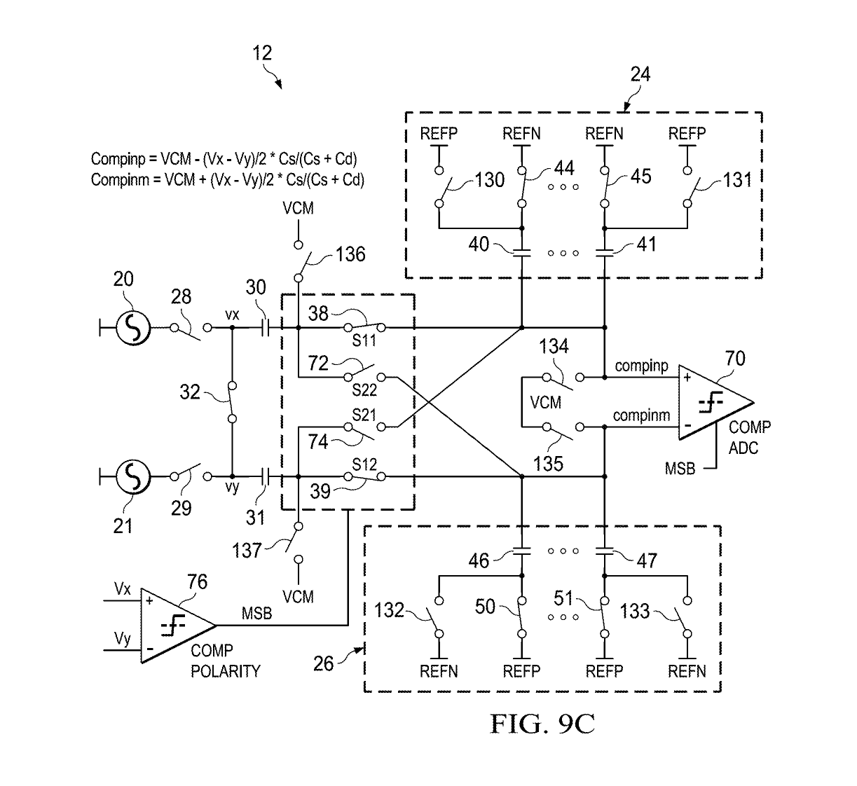

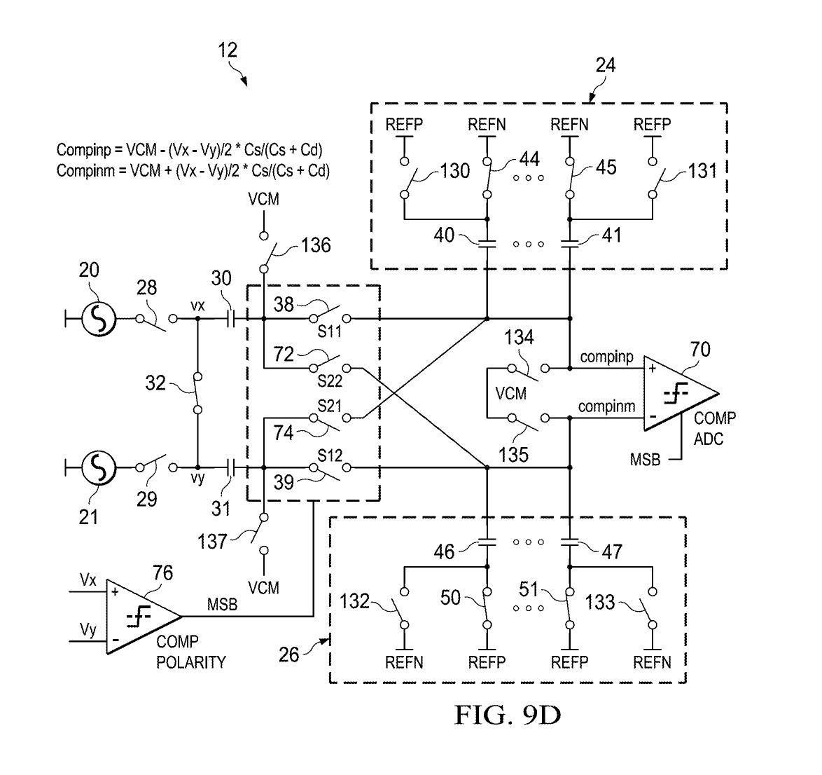

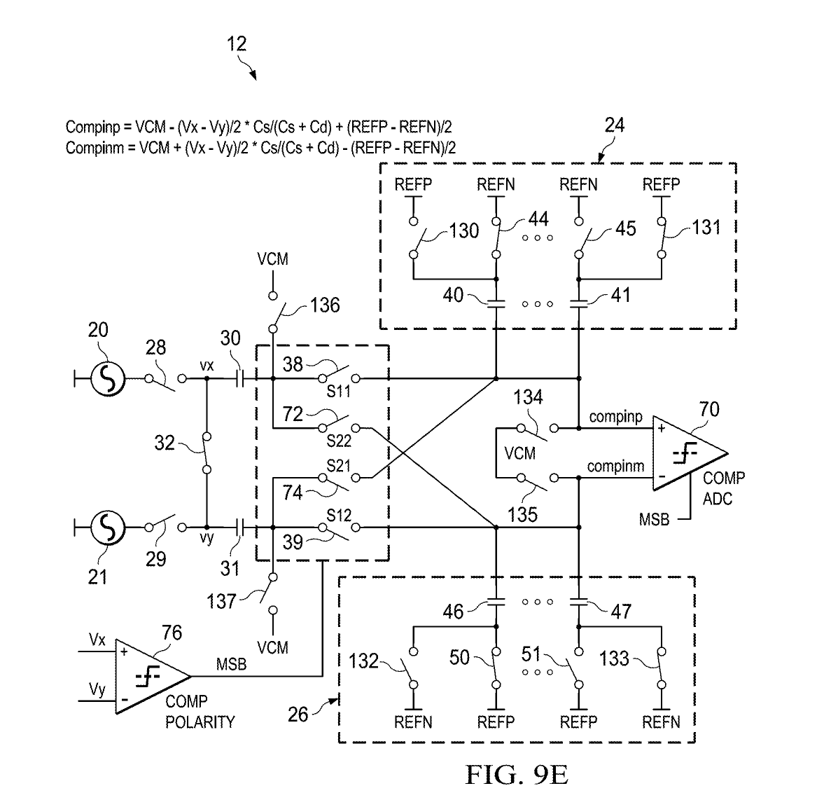

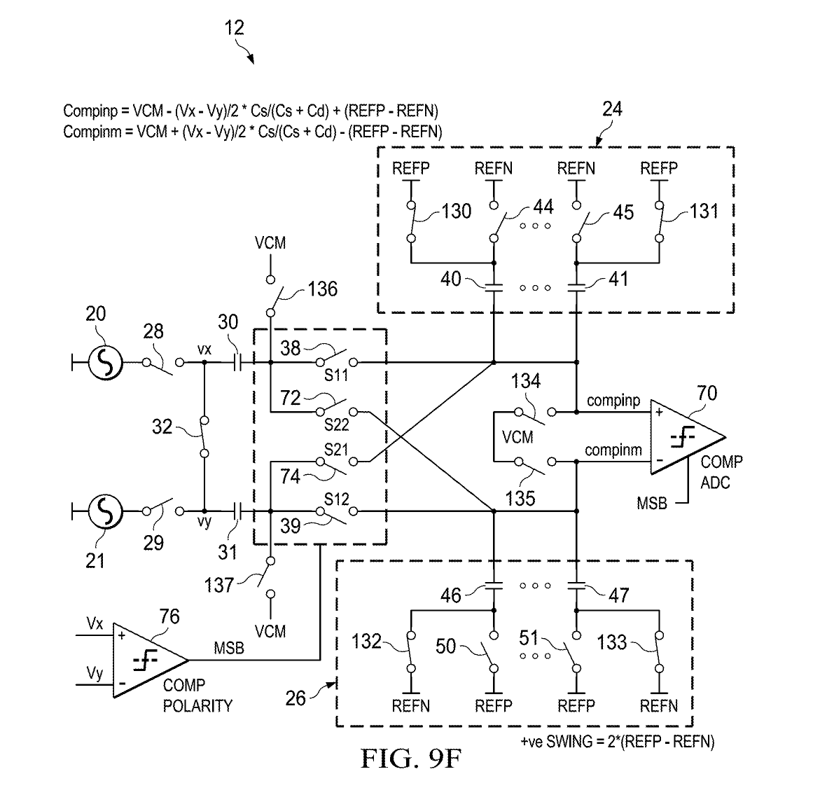

Turning to FIGS. 9A-9F, FIGS. 9A-9F are simplified electrical circuit diagrams illustrating example details and operations of an example embodiment of system 10. Wide swing ADC 12 may support ±2×V_{REF}, where V_{REF} is the reference voltage, potentially having lower reference noise for the same swing. Wide swing ADC 12 includes a comparator 70 connected to PDAC 24 on its positive terminal and to NDAC 26 on its negative terminal. ADC 12 includes sampling capacitors 30, 31 and conversion capacitors 40 and 41 in PDAC 24, and 46 and 47 in NDAC 26. ADC 12 includes, in addition to switches 28, 29, 32, 38, 39, 44, 45, 50 and 51, additional decoupling switches 72 and 74 that can selectively change connections of sampling capacitors 30 and 31 to PDAC 24 and NDAC 26, for example, depending on inputs Vx and Vy to a polarity comparator 76. The output of polarity comparator 76 is also the MSB of the analog-to-digital conversion.

In some embodiments, conversion capacitors 40 and 41 in PDAC 24 and 46 and 47 in NDAC 26 may be connected to positive or negative reference voltages based on additional reference switches 130, 131, 132 and 133. For example, conversion capacitor 40 may be connected to a negative reference voltage when switch 44 is closed and switch 130 is open; conversely, conversion capacitor 40 may be connected to a positive reference voltage when switch 44 is open and switch 130 is closed. Likewise, conversion capacitor 41 may be connected to a negative reference voltage when switch 45 is closed and switch 131 is open; conversely, conversion capacitor 41 may be connected to a positive reference voltage when switch 45 is open and switch 131 is closed. Similarly, conversion capacitor 46 may be connected to a negative reference voltage when switch 132 is closed and switch 50 is open; conversely, conversion capacitor 46 may be connected to a positive reference voltage when switch 132 is open and switch 50 is closed. Conversion capacitor 47 may be connected to a negative reference voltage when switch 133 is closed and switch 51 is open; conversely, conversion capacitor 47 may be connected to a positive reference voltage when switch 133 is open and switch 51 is closed.

In some embodiments, additional VCM switches 134, 135, 136 and 137 may be provided to connect various terminals to the common mode voltage (V_{CM}). During operation, various switches may be opened and closed based on inputs to comparator 76; in other words, depending on whether Vx is greater than Vy. Assume, merely for example purposes, that Vx is greater than Vy. As indicated in FIG. 9A, in sampling phase 82, VCM switches 134, 135, 136 and 137 may be closed such that inputs (compinp and compinm) to comparator 70 may be equal to V_{CM}; and with input switches 28 and 29 closed, input voltages 20 and 21 charge sampling capacitors 30 and 31. As indicated in FIG. 9B, at the end of sampling phase 82, input switches 28 and 29 are opened, and VCM switches 134, 135, 136 and 137 are opened. Polarity comparator 76 selects to close decoupling switches 38 and 39 because Vx>Vy. As indicated in FIG. 9C, during charge transfer phase 84, discharge switch 32 is closed, and charges in sampling capacitors 30 and 31 are distributed to conversion capacitors in PDAC 24 and NDAC 26, respectively. Inputs to comparator 70 would be as follows:

compinp=V_{CM}−(Vx−Vy)/2*Cs/(Cs+Cd); and

compinm=V_{CM}+(Vx−Vy)/2*Cs/(Cs+Cd).

As indicated in FIG. 9D, at the end of charge transfer phase 84, decoupling switches 38 and 39 are opened. Reference switches 44, 45, 50 and 51 are closed. As indicated in FIG. 9E, a second bit trial phase 82 may start concurrently, wherein decoupling switches 38, 39, 72, and 74 are all turned off (e.g., open), and reference switches 44 and 131 in PDAC 24 and 50 and 133 in NDAC 26 are closed and reference switches 45, 130, 51 and 132 are open. Thus, half the PDAC capacitors and half the NDAC capacitors are connected to the positive reference voltage (REFP) and the other half to the negative reference voltage (REFN). Such an arrangement can generate a top plate voltage change of V_{REF}/2 in PDAC 24 and −V_{REF}/2 in NDAC 26. Inputs to comparator 70 would be as follows:

compinp=V_{CM}−(Vx−Vy)/2*Cs/(Cs+Cd)+(REFP−REFN)/2; and

compinm=V_{CM}+(Vx−Vy)/2*Cs/(Cs+Cd)−(REFP−REFN)/2.

As indicated in FIG. 9F, for a full range on positive side (e.g., full range=2*(REFP−REFN), where (REFP−REFN) represents V_{REF}) decoupling switches 38, 39, 72, and 74 are all turned off (e.g., open), reference switches 44 and 45 in PDAC 24 and 50 and 51 in NDAC 26 are open and reference switches 130, 131, 132 and 133 are open. Such an arrangement can provide a maximum voltage swing of ±2×V_{REF}. Inputs to comparator 70 would be as follows:

compinp=V_{CM}−(Vx−Vy)/2*Cs/(Cs+Cd)+(REFP−REFN); and

compinm=V_{CM}+(Vx−Vy)/2*Cs/(Cs+Cd)−(REFP−REFN).

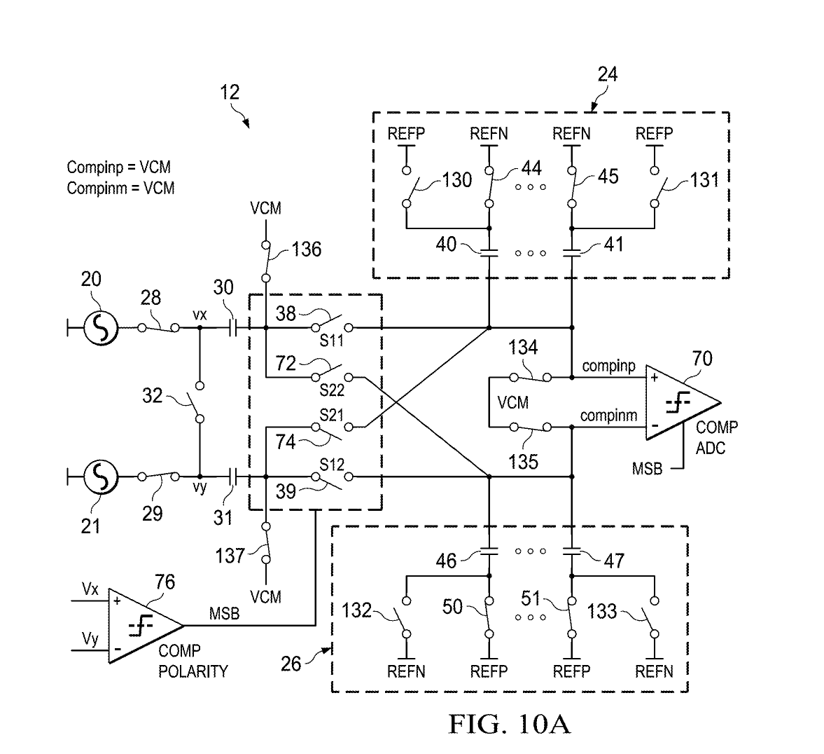

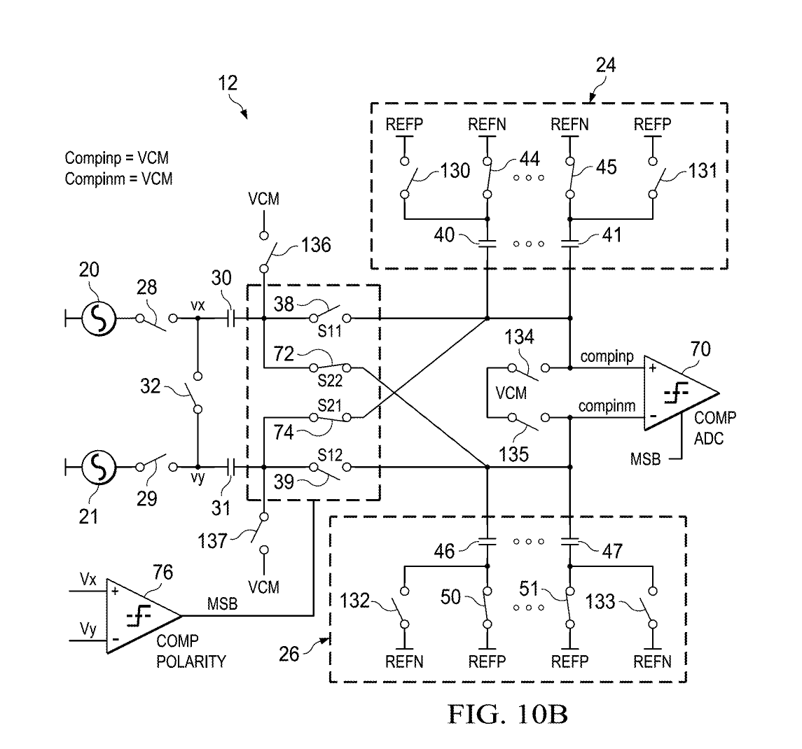

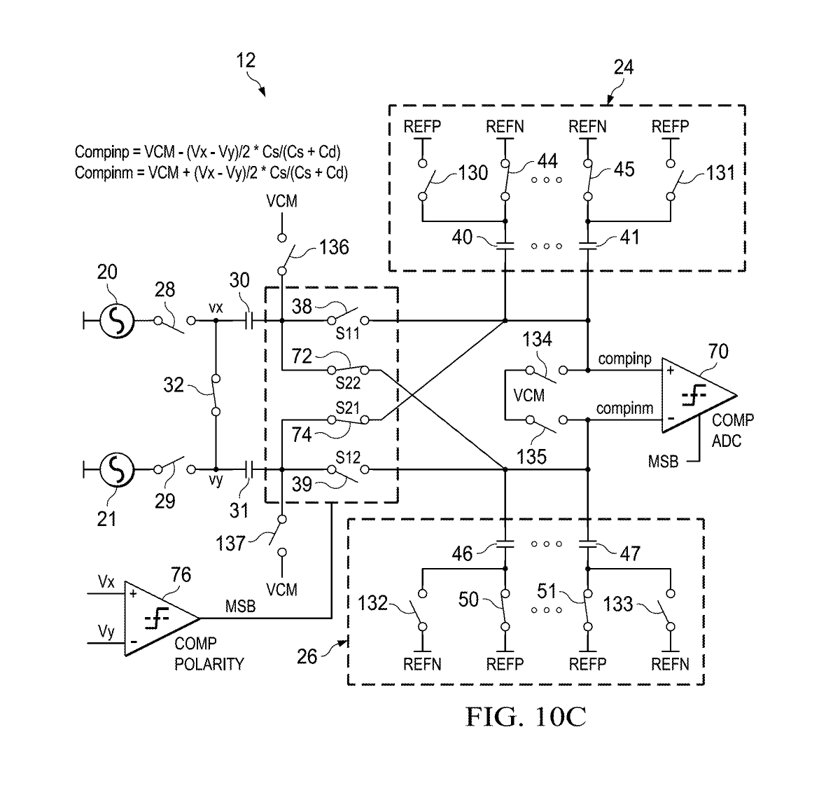

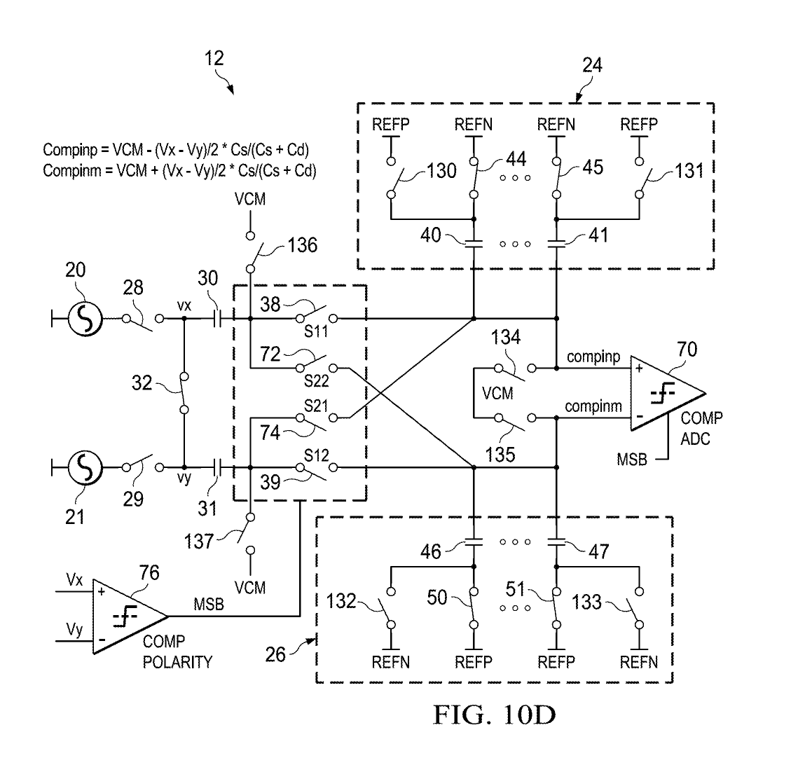

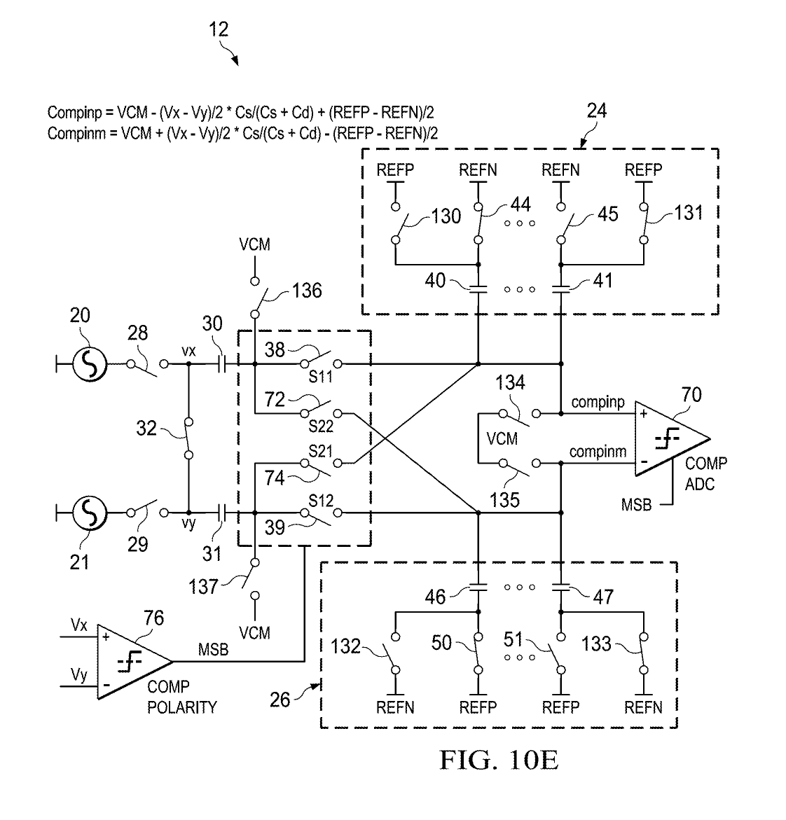

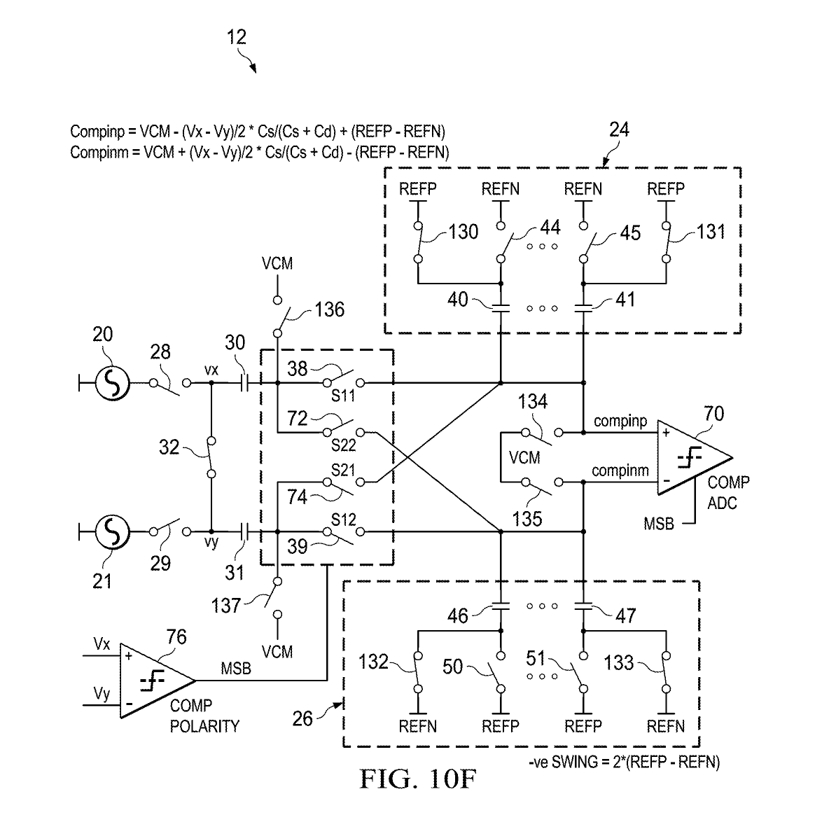

Turning to FIGS. 10A-10F, FIGS. 10A-10F are simplified electrical circuit diagrams illustrating example details and operations of an example embodiment of system 10. Assume, merely for example purposes, that Vx is less than Vy. As indicated in FIG. 10A, in sampling phase 82, VCM switches 134, 135, 136 and 137 may be closed such that inputs (compinp and compinm) to comparator 70 may be equal to V_{CM}; and with input switches 28 and 29 closed, input voltages 20 and 21 charge sampling capacitors 30 and 31. As indicated in FIG. 10B, at the end of sampling phase 82, input switches 28 and 29 are opened, and VCM switches 134, 135, 136 and 137 are opened. Polarity comparator 76 selects to open decoupling switches 38 and 39 and close decoupling switches 72 and 74 because Vx<Vy. As indicated in FIG. 10C, during charge transfer phase 84, discharge switch 32 is closed, and charges in sampling capacitors 30 and 31 are distributed to conversion capacitors in NDAC 26 and PDAC 24, respectively. Inputs to comparator 70 would be as follows:

compinp=V_{CM}−(Vy−Vx)/2*Cs/(Cs+Cd); and

compinm=V_{CM}+(Vy−Vx)/2*Cs/(Cs+Cd).

As indicated in FIG. 10D, at the end of charge transfer phase 84, decoupling switches 72 and 74 are opened. Reference switches 44, 45, 50 and 51 are closed. As indicated in FIG. 10E, a second bit trial phase 82 may start concurrently, wherein decoupling switches 38, 39, 72, and 74 are all turned off (e.g., open), and reference switches 44 and 131 in PDAC 24 and 50 and 133 in NDAC 26 are closed and reference switches 45, 130, 51 and 132 are open. Inputs to comparator 70 would be as follows:

compinp=V_{CM}−(Vy−Vx)/2*Cs/(Cs+Cd)+(REFP−REFN)/2; and

compinm=V_{CM}+(Vy−Vx)/2*Cs/(Cs+Cd)−(REFP−REFN)/2.

As indicated in FIG. 10F, for a full range on positive side (e.g., full range=2*(REFP−REFN), where (REFP−REFN) represents V_{REF}) decoupling switches 38, 39, 72, and 74 are all turned off (e.g., open), reference switches 44 and 45 in PDAC 24 and 50 and 51 in NDAC 26 are open and reference switches 130, 131, 132 and 133 are open. Inputs to comparator 70 would be as follows:

compinp=V_{CM}−(Vy−Vx)/2*Cs/(Cs+Cd)+(REFP−REFN); and

compinm=V_{CM}+(Vy−Vx)/2*Cs/(Cs+Cd)−(REFP−REFN).

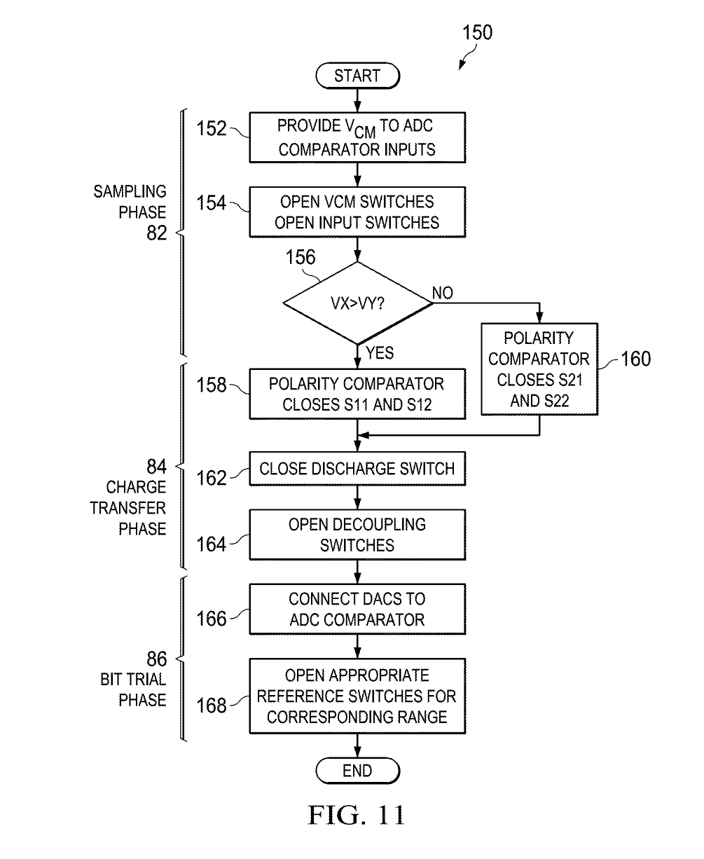

Turning to FIG. 11, FIG. 11 is a simplified flow diagram illustrating example operations 150 that may be associated with embodiments of system 10 that may be used in conjunction with a wide swing ADC. At 152, common mode voltage V_{CM} may be provided to inputs of ADC comparator 70, for example, by closing VCM switches 134, 135, 136 and 137. At 154, VCM switches 134, 135, 136 and 137 may be opened and input switches 28 and 29 may be closed. At 156, polarity comparator 76 may make a comparison between its input voltages Vx and Vy and determine whether Vx is greater than Vy. If Vx>Vy, at 158, polarity comparator 76 may close decoupling switches 38 and 39 (S11 and S12). On the other hand, if Vx<Vy, at 160, polarity comparator 76 may close decoupling switches 72 and 74 (S21 and S22). At 162, discharge switch 32 may be closed. At 164, any closed decoupling switches may be opened. At 166, PDAC 24 and NDAC 26 may be connected to ADC comparator 70. At 168, appropriate reference switches may be opened for converting inputs at corresponding reference voltage ranges.

Note that in this Specification, references to various features (e.g., elements, structures, modules, components, steps, operations, characteristics, etc.) included in “one embodiment”, “example embodiment”, “an embodiment”, “another embodiment”, “some embodiments”, “various embodiments”, “other embodiments”, “alternative embodiment”, and the like are intended to mean that any such features are included in one or more embodiments of the present disclosure, but may or may not necessarily be combined in the same embodiments.

In the various embodiments described herein, a plurality of switches are indicated, the switches comprising any suitable electrical component that can temporarily interrupt current flowing through a conductor. In example embodiments, the switches may comprise power semiconductor devices, such as power diode, thyristor, power Metal Oxide Semiconductor Field Effect Transistor (MOSFET), and insulated gate bipolar transistor (IGBT). The switches may be turned on or off by suitable control circuitry that is not shown in the figures. In various embodiments, the switches may be turned on or off based on various parameters, including (without limitations) time (e.g., measured from a start of application of the analog input voltage), voltage, and charge (e.g., in sampling capacitors).

In the discussions of the embodiments above, circuit components, such as capacitors, clocks, dividers, inductors, resistors, amplifiers, switches, digital core, transistors, and/or other components can readily be replaced, substituted, or otherwise modified in order to accommodate particular circuitry needs. Moreover, it should be noted that the use of complementary electronic chips, hardware, software, etc. offer an equally viable option for implementing the teachings of the present disclosure.

In one example embodiment, any number of electrical circuits of the FIGURES may be implemented on a board of an associated electronic chip. The board can be a general circuit board that can hold various components of the internal electronic system of the electronic chip and, further, provide connectors for other peripherals. More specifically, the board can provide the electrical connections by which the other components of the system can communicate electrically. Any suitable processors (inclusive of digital signal processors, microprocessors, supporting chipsets, etc.), memory elements, etc. can be suitably coupled to the board based on particular configuration needs, processing demands, computer designs, etc. Other components such as external storage, additional sensors, controllers for audio/video display, and other peripheral chips may be attached to the board as plug-in cards, via cables, or integrated into the board itself.

In another example embodiment, the electrical circuits of the FIGURES may be implemented as stand-alone modules (e.g., a chip with associated components and circuitry configured to perform a specific application or function) or implemented as plug-in modules into application specific hardware of electronic chips. Note that particular embodiments of the present disclosure may be readily included in a system on chip (SOC) package, either in part, or in whole. An SOC represents an IC that integrates components of a computer or other electronic system into a single chip. It may contain digital, analog, mixed-signal, and often radio frequency functions: all of which may be provided on a single chip substrate. Other embodiments may include a multi-chip-module (MCM), with a plurality of separate ICs located within a single electronic package and configured to interact closely with each other through the electronic package. In various other embodiments, the functionalities as described herein may be implemented in one or more silicon cores in Application Specific Integrated Circuits (ASICs), Field Programmable Gate Arrays (FPGAs), and other semiconductor chips. In various other embodiments, the functionalities described herein may be implemented in emulation form as software or firmware running within one or more configurable (e.g., programmable) elements arranged in a structure that supports these functions.

It is also imperative to note that all of the specifications, dimensions, and relationships outlined herein (e.g., the number of components, logic operations, etc.) have only been offered for purposes of example and teaching only. Such information may be varied considerably without departing from the spirit of the present disclosure, or the scope of the appended claims. The specifications apply only to one non-limiting example and, accordingly, they should be construed as such. In the foregoing description, example embodiments have been described with reference to particular component arrangements. Various modifications and changes may be made to such embodiments without departing from the scope of the appended claims. The description and drawings are, accordingly, to be regarded in an illustrative rather than in a restrictive sense.

Note that the activities discussed above with reference to the FIGURES are applicable to any integrated circuits that involve signal processing, particularly those that rely on signals to execute specialized software programs, or algorithms, some of which may be associated with processing digitized real-time data. Certain embodiments can relate to automotive applications, such as battery power sensors and related accessories. Certain other embodiments can relate to multi-DSP signal processing, floating point processing, signal/control processing, fixed-function processing, microcontroller applications, etc. In certain contexts, the features discussed herein can be applicable to automotive systems, medical systems, scientific instrumentation, wireless and wired communications, radar, industrial process control, audio and video equipment, current sensing, instrumentation (which can be highly precise), and other digital-processing-based systems.

Moreover, certain embodiments discussed above can be provisioned in digital signal processing technologies for medical imaging, patient monitoring, medical instrumentation, and home healthcare. This could include pulmonary monitors, accelerometers, heart rate monitors, pacemakers, etc. Other applications can involve automotive technologies for safety systems (e.g., stability control systems, driver assistance systems, braking systems, infotainment and interior applications of any kind). Furthermore, powertrain systems (for example, in hybrid and electric vehicles) can apply the functionalities described herein in high-precision data conversion products in battery monitoring, control systems, reporting controls, maintenance activities, etc.

In yet other example scenarios, the teachings of the present disclosure can be applicable in the industrial markets that include process control systems that help drive productivity, energy efficiency, and reliability. In consumer applications, the teachings of the electrical circuits discussed above can be used for image processing, auto focus, and image stabilization (e.g., for digital still cameras, camcorders, etc.). Other consumer applications can include audio and video processors for home theater systems, DVD recorders, and high-definition televisions. Yet other consumer applications can involve advanced touch screen controllers (e.g., for any type of portable media chip). Hence, such technologies could readily part of smartphones, tablets, security systems, PCs, gaming technologies, virtual reality, simulation training, etc.

Note that with the numerous examples provided herein, interaction may be described in terms of two, three, four, or more electrical components. However, this has been done for purposes of clarity and example only. It should be appreciated that the system can be consolidated in any suitable manner. Along similar design alternatives, any of the illustrated components, modules, and elements of the FIGURES may be combined in various possible configurations, all of which are clearly within the broad scope of this Specification. In certain cases, it may be easier to describe one or more of the functionalities of a given set of flows by only referencing a limited number of electrical elements. It should be appreciated that the electrical circuits of the FIGURES and its teachings are readily scalable and can accommodate a large number of components, as well as more complicated/sophisticated arrangements and configurations. Accordingly, the examples provided should not limit the scope or inhibit the broad teachings of the electrical circuits as potentially applied to a myriad of other architectures.

It is also important to note that the operations and steps described with reference to the preceding FIGURES illustrate only some of the possible scenarios that may be executed by, or within, the system. Some of these operations may be deleted or removed where appropriate, or these steps may be modified or changed considerably without departing from the scope of the discussed concepts. In addition, the timing and/or sequence of these operations may be altered considerably and still achieve the results taught in this disclosure. The preceding operational flows have been offered for purposes of example and discussion. Substantial flexibility is provided by the system in that any suitable arrangements, chronologies, configurations, and timing mechanisms may be provided without departing from the teachings of the discussed concepts.

Numerous other changes, substitutions, variations, alterations, and modifications may be ascertained to one skilled in the art and it is intended that the present disclosure encompass all such changes, substitutions, variations, alterations, and modifications as falling within the scope of the appended claims. In order to assist the United States Patent and Trademark Office (USPTO) and, additionally, any readers of any patent issued on this application in interpreting the claims appended hereto, Applicant wishes to note that the Applicant: (a) does not intend any of the appended claims to invoke paragraph six (6) of 35 U.S.C. section 112 as it exists on the date of the filing hereof unless the words “means for” or “step for” are specifically used in the particular claims; and (b) does not intend, by any statement in the specification, to limit this disclosure in any way that is not otherwise reflected in the appended claims.

### OTHER NOTES, EXAMPLES, AND IMPLEMENTATIONS

Note that all optional features of the apparatus described above may also be implemented with respect to the method or process described herein and specifics in the examples may be used anywhere in one or more embodiments. In a first example, a system is provided (that can include any suitable circuitry, dividers, capacitors, resistors, inductors, ADCs, DFFs, logic gates, software, hardware, links, etc.) that can be part of any type of electronic device (e.g., computer), which can further include a circuit board coupled to a plurality of electronic components. The system can include an ADC that includes a pair of binary weighted conversion capacitor arrays, a pair of sampling capacitors, and a plurality of switches, with means for performing a sampling phase, a charge transfer phase and a bit trial phase.

The ADC includes means for decoupling the sampling capacitors from the conversion capacitor arrays, means for coupling bottom plates of the sampling capacitors to an analog input voltage, means for coupling top plates of the sampling capacitors to a common-mode voltage (V_{CM}), and means for applying the analog input voltage to charge the sampling capacitors accordingly during the sampling phase. The ADC also includes means for decoupling the bottom plates of the sampling capacitors from the analog input voltage, means for shorting the bottom plates of the sampling capacitors to each other, means for decoupling the top plates of the sampling capacitors from the common-mode voltage, and means for coupling the top plates of the sampling capacitors to top plates of the conversion capacitors to distribute charge in the sampling capacitors to the conversion capacitors during the charge transfer phase. The ADC also includes means for decoupling the sampling capacitors from the conversion capacitors, and means for coupling top plates of the conversion capacitors to a differential comparator during the bit trial phase.

The ‘means for’ in these instances (above) can include (but is not limited to) using any suitable component discussed herein, along with any suitable software, circuitry, hub, computer code, logic, algorithms, hardware, controller, interface, link, bus, communication pathway, etc. In a second example, the system includes memory that further comprises machine-readable instructions that when executed cause the system to perform any of the activities discussed above.

1. An analog to digital converter (ADC) facilitating passive analog sample and hold, comprising:
a pair of binary weighted conversion capacitor arrays;
a pair of sampling capacitors, wherein a sampling capacitance (Cs) of the sampling capacitors is a multiple of a conversion capacitance (Cd) of the conversion capacitors (Cs=N×Cd);
integral nonlinearity (INL) compensation capacitors coupled to the sampling capacitors, wherein a ratio of a capacitance (Cp_{d}) of the INL compensation capacitors to a parasitic capacitance (Cpₛ) of the conversion capacitors is equal to the multiplier associated with the sampling capacitance (Cs) and the conversion capacitance (Cd) (Cp_{d}=N×Cpₛ); and
a plurality of switches that configure each conversion capacitor array and the sampling capacitors for a sampling phase, a charge transfer phase, and a bit trial phase,
wherein, during the sampling phase, the sampling capacitors are decoupled from the conversion capacitors and coupled to an analog input voltage,
wherein, during the charge transfer phase, the sampling capacitors are coupled to the conversion capacitors and decoupled from the analog input voltage, and
wherein, during the bit trial phase, the sampling capacitors are decoupled from the conversion capacitors.

2. The ADC of claim 1, wherein the multiplier is greater than 1 (Cs=N×Cd, N>1).

3. (canceled)

4. The ADC of claim 1, wherein the INL compensation is achieved by trimming dummy switches with their source and drain shorted and a control signal applied to the gate terminals, wherein the switch capacitance is lower when the switches are turned off than when they are turned on, wherein the dummy switch capacitance can be varied by changing the control signal voltage at the gate terminals.

5. The ADC of claim 1, wherein the sampling phase, the charge transfer phase and the bit trial phase comprise a passive sampling scheme that decouples input and reference attenuation factors and reduces input and reference attenuation.

6. The ADC of claim 1, wherein the ADC can convert a maximum analog input signal having a range of up to four times a reference voltage (0-4×V_{REF}).

7. The ADC of claim 1, wherein the ADC can convert a maximum analog input signal having a range of plus or minus twice a reference voltage (±2×V_{REF}).

8. The ADC of claim 1, wherein during the bit trial phase, the conversion capacitor arrays are decoupled from the sampling capacitors and connected to a differential comparator.

9. The ADC of claim 1, wherein each sampling capacitor includes a bottom plate and a top plate, wherein the bottom plates are selectively coupled to one of the analog input voltage, auxiliary buffers, and a discharge switch that, in a closed configuration, shorts the bottom plates together, wherein the top plates are selectively coupled to one of a common-mode voltage and the conversion capacitor arrays.

10. The ADC of claim 9, wherein, during the charge transfer phase, the discharge switch is in the closed configuration, wherein, during the sampling phase and the bit trial phase, the discharge switch is not in the closed configuration.

11. The ADC of claim 1, wherein each sampling capacitor includes a bottom plate and a top plate, wherein the bottom plates are selectively coupled to one of the analog input voltage, auxiliary buffers, and a fixed voltage, wherein the top plates are selectively coupled to one of a common-mode voltage and the conversion capacitor arrays, wherein the bottom plates of the sampling capacitors are connected to the analog input voltage during the sampling phase, and to the fixed voltage during the charge transfer phase.

12. The ADC of claim 1, wherein the plurality of switches include decoupling switches, wherein in an open configuration of the decoupling switches, the sampling capacitors are decoupled from the conversion capacitor arrays, wherein in a closed configuration of the decoupling switches, the sampling capacitors are coupled to the conversion capacitor arrays.

13. The ADC of claim 1, wherein the plurality of switches include additional decoupling switches that force voltages across sampling capacitors and the conversion capacitor arrays to have a swing of plus or minus twice a reference voltage (±2V_{REF}).

14. The ADC of claim 1, wherein,
during the sampling phase, top plates of the sampling capacitors are coupled to a common-mode voltage (V_{CM}), bottom plates of the sampling capacitors are coupled to the analog input voltage, top plates of the conversion capacitor arrays are coupled to the V_{CM}, and bottom plates of the conversion capacitor arrays are coupled to a reference voltage (V_{REF}),
during the charge transfer phase, top plates of the sampling capacitors are coupled to top plates of the conversion capacitor arrays, bottom plates of the sampling capacitors are shorted together, and bottom plates of the conversion capacitor arrays are coupled to the V_{REF}, and
during the bit trial phase, top plates of the sampling capacitors are coupled to the C_{CM}, bottom plates of the sampling capacitors are coupled to auxiliary buffers, top plates of the conversion capacitor arrays are coupled to a differential comparator and bottom plates of the conversion capacitor arrays are coupled to the V_{REF}.

15. The ADC of claim 14, wherein the auxiliary buffers pre-charge the sampling capacitors to a voltage close to the analog input voltage.

16. The ADC of claim 14, wherein, during the bit trial phase, after the sampling capacitors are pre-charged, the sampling capacitors are coupled to a second analog input voltage to start a second sampling phase concurrently.

17. A method for passive analog sample and hold in an ADC comprising a pair of binary weighted conversion capacitor arrays, a pair of sampling capacitors, integral nonlinearity (INL) compensation capacitors coupled to the sampling capacitors, and a plurality of switches, the method comprising:
a sampling phase,
a charge transfer phase; and
a bit trial phase, wherein a sampling capacitance (Cs) of the sampling capacitors is a multiple of a conversion capacitance (Cd) of the conversion capacitors (Cs=N×Cd), and a ratio of a capacitance (Cp_{d}) of the INL compensation capacitors to a parasitic capacitance (Cpₛ) of the conversion capacitors is equal to the multiplier associated with the sampling capacitance (Cs) and the conversion capacitance (Cd)(Cp_{d}=N×Cpₛ).

18. The method of claim 17, wherein the sampling phase comprises:
decoupling the sampling capacitors from the conversion capacitor arrays;
coupling bottom plates of the sampling capacitors to an analog input voltage;
coupling top plates of the sampling capacitors to a common-mode voltage (V_{CM}); and
applying the analog input voltage to charge the sampling capacitors accordingly.

19. The method of claim 17, wherein the charge transfer phase comprises:
decoupling the bottom plates of the sampling capacitors from the analog input voltage;
shorting the bottom plates of the sampling capacitors to each other;
decoupling the top plates of the sampling capacitors from the common-mode voltage; and
coupling the top plates of the sampling capacitors to top plates of the conversion capacitors to distribute charge in the sampling capacitors to the conversion capacitors.

20. The method of claim 17, wherein the bit trial phase comprises:
decoupling the sampling capacitors from the conversion capacitors; and
coupling top plates of the conversion capacitors to a differential comparator.
